(19) United States
(12) Patent Application Publication
(10) Pub. No.: US 2025/0269464 A1
(43) Pub. Date: Aug. 28, 2025

(54) LASER PROCESSING APPARATUS, LASER PROCESSING APPARATUS CONTROL METHOD, AND ELECTRONIC DEVICE MANUFACTURING METHOD

(71) Applicant: Gigaphoton Inc., Tochigi (JP)

(72) Inventors: Yasufumi KAWASUJI, Oyama-shi (JP); Osamu Wakabayashi, Oyama-shi (JP); Akiyoshi Suzuki, Oyama-shi (JP)

(73) Assignee: Gigaphoton Inc., Tochigi (JP)

(21) Appl. No.: 19/196,455

(22) Filed: May 1, 2025

Related U.S. Application Data
(63) Continuation of application No. PCT/JP2022/046969, filed on Dec. 20, 2022.

(51) Int. Cl. B23K 26/08; G02B 19/00; G02B 26/02; G02B 27/10; H01L 21/48

(52) U.S. Cl. CPC B23K 26/083; G02B 19/0009; G02B 19/0047; G02B 26/023; G02B 27/1093; H01L 21/486

(57) ABSTRACT

A laser processing apparatus includes a diffractive optical element dividing first laser light into beams of second laser light and output the second laser light, a light concentrating optical system generating a multi-point pattern in which concentration spots are arranged in a grid-like manner, a first actuator moving a workpiece, a light shielding plate capable of shielding at least one row and at least one column of the multi-point pattern, a second actuator changing a relative position of the light shielding plate with respect to the multi-point pattern so as to select one of first to fourth multi-point patterns, and a laser processing processor controlling the first actuator to move the workpiece such that any one of the first to fourth multi-point patterns is radiated to each step position and controlling the second actuator to select one of the first to fourth multi-point patterns for each step position.

### CROSS-REFERENCE TO RELATED APPLICATIONS

The present application is a continuation application of International Application No. PCT/JP2022/046969, filed on Dec. 20, 2022, the entire contents of which are hereby incorporated by reference.

### BACKGROUND

### 1. Technical Field

The present disclosure relates to a laser processing apparatus, a laser processing apparatus control method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as the gas laser device for exposure, a KrF excimer laser device that outputs laser light having a wavelength of about 248.4 nm and an ArF excimer laser device that outputs laser light having a wavelength of about 193.4 nm are used.

Since excimer laser light has a pulse width of about several tens of ns and a wavelength is short as 248.4 nm or 193.4 nm, excimer laser light is sometimes used for direct processing of a polymer material, a glass material, or the like.

Chemical bonds in polymeric materials can be broken by excimer laser light having a photon energy higher than the bond energy. Therefore, it is known that non-heating processing of polymeric materials is possible with excimer laser light, and that the processing shape is beautiful.

Further, it is known that, since glass, ceramics, and the like have high absorptance with respect to excimer laser light, even a material that is difficult to be processed with visible and infrared laser light can be processed with excimer laser light.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2006/0289412
Patent Document 2: Japanese Patent Application Publication No. 2007-268600

### SUMMARY

A laser processing apparatus according to an aspect of the present disclosure includes a diffractive optical element configured to divide first laser light into a plurality of beams of second laser light and output the plurality of beams of second laser light; a light concentrating optical system configured to generate a multi-point pattern in which a plurality of concentration spots are arranged in a grid-like manner in a row direction and a column direction by concentrating the plurality of beams of second laser light; a first actuator configured to move a workpiece; a light shielding plate capable of shielding at least one row and at least one column of the multi-point pattern; a second actuator configured to change a relative position of the light shielding plate with respect to the multi-point pattern so as to select one of a first multi-point pattern generated by the multi-point pattern passing through without being shielded by the light shielding plate, a second multi-point pattern generated by at least one row of the multi-point pattern being shielded by the light shielding plate, a third multi-point pattern generated by at least one row and at least one column of the multi-point pattern being shielded by the light shielding plate, and a fourth multi-point pattern generated by at least one column of the multi-point pattern being shielded by the light shielding plate; and a laser processing processor configured to control the first actuator to move the workpiece such that any one of the first to fourth multi-point patterns is radiated to each of a plurality of step positions set in a processing area that requires drilling on a surface of the workpiece, and control the second actuator to select one of the first to fourth multi-point patterns for each of the step positions.

A laser processing apparatus control method according to an aspect of the present disclosure includes controlling a first actuator to move a workpiece such that any one of first to fourth multi-point patterns is radiated to each of a plurality of step positions set in a processing area that requires drilling on a surface of the workpiece; and controlling a second actuator to select one of the first to fourth multi-point patterns for each of the step positions. Here, the laser processing apparatus includes a diffractive optical element configured to divide first laser light into a plurality of beams of second laser light and output the plurality of beams of second laser light; a light concentrating optical system configured to generate a multi-point pattern in which a plurality of concentration spots are arranged in a grid-like manner in a row direction and a column direction by concentrating the plurality of beams of second laser light; the first actuator configured to move the workpiece; a light shielding plate capable of shielding at least one row and at least one column of the multi-point pattern; and the second actuator configured to change a relative position of the light shielding plate with respect to the multi-point pattern so as to select one of the first multi-point pattern generated by the multi-point pattern passing through without being shielded by the light shielding plate, the second multi-point pattern generated by at least one row of the multi-point pattern being shielded by the light shielding plate, the third multi-point pattern generated by at least one row and at least one column of the multi-point pattern being shielded by the light shielding plate, and the fourth multi-point pattern generated by at least one column of the multi-point pattern being shielded by the light shielding plate.

An electronic device manufacturing method according to an aspect of the present disclosure includes forming a plurality of through holes in a glass substrate as a workpiece with a laser processing apparatus; coupling and electrically connecting an interposer and an integrated circuit chip to each other, the interposer including the glass substrate and a conductor arranged in each of the plurality of through holes; and coupling and electrically connecting the interposer and a circuit substrate to each other. Here, the laser processing apparatus includes a diffractive optical element configured to divide first laser light into a plurality of beams of second laser light and output the plurality of beams of second laser light; a light concentrating optical system configured to generate a multi-point pattern in which a plurality of concentration spots are arranged in a grid-like manner in a row direction and a column direction by concentrating the plurality of beams of second laser light; a first actuator configured to move the workpiece; a light shielding plate capable of shielding at least one row and at least one column of the multi-point pattern; a second actuator configured to change a relative position of the light shielding plate with respect to the multi-point pattern so as to select one of a first multi-point pattern generated by the multi-point pattern passing through without being shielded by the light shielding plate, a second multi-point pattern generated by at least one row of the multi-point pattern being shielded by the light shielding plate, a third multi-point pattern generated by at least one row and at least one column of the multi-point pattern being shielded by the light shielding plate, and a fourth multi-point pattern generated by at least one column of the multi-point pattern being shielded by the light shielding plate; and a laser processing processor configured to control the first actuator to move the workpiece such that any one of the first to fourth multi-point patterns is radiated to each of a plurality of step positions set in a processing area that requires drilling on a surface of the workpiece, and control the second actuator to select one of the first to fourth multi-point patterns for each of the step positions.

### BRIEF DESCRIPTION OF THE DRAWINGS

Embodiments of the present disclosure will be described below merely as examples with reference to the accompanying drawings.

FIG. 1 is a view schematically showing the configuration of a laser processing system according to a comparative example.

FIG. 2 is a view schematically showing the configuration of a laser device.

FIG. 3 is a diagram showing the flow of operation of the laser processing system according to the comparative example.

FIG. 4 is a diagram showing details of a process of reading processing conditions.

FIG. 5 is a diagram showing details of a fluence adjustment process.

FIG. 6 is a diagram showing details of a drilling process.

FIG. 7 is a view showing an example of a multi-point pattern.

FIG. 8 is a view showing an example of a processing area that requires drilling.

FIG. 9 is a view showing an example of a plurality of step positions.

FIG. 10 is a view showing an example of a surface of a workpiece after drilling.

FIG. 11 is a view schematically showing the configuration of the laser processing system according to a first embodiment.

FIG. 12 is a view showing an example of a first position of a light shielding plate.

FIG. 13 is a view showing an example of a second position of the light shielding plate.

FIG. 14 is a view showing an example of a third position of the light shielding plate.

FIG. 15 is a view showing an example of a fourth position of the light shielding plate.

FIG. 16 is a view showing an example of the plurality of step positions.

FIG. 17 is a diagram schematically showing the flow of operation of the laser processing system according to the first embodiment.

FIG. 18 is a diagram showing details of processes of generating and storing position data.

FIG. 19 is a diagram showing details of a process of determining first to fourth areas and a movement path.

FIG. 20 is a diagram showing details of the drilling process.

FIG. 21 is a view showing an example of the first position of the light shielding plate according to a modification of the first embodiment.

FIG. 22 is a view showing an example of the second position of the light shielding plate according to the modification of the first embodiment.

FIG. 23 is a view showing an example of the third position of the light shielding plate according to the modification of the first embodiment.

FIG. 24 is a view showing an example of the fourth position of the light shielding plate according to the modification of the first embodiment.

FIG. 25 is a view showing an example of the plurality of step positions set by the laser processing processor according to the modification of the first embodiment.

FIG. 26 is a diagram showing details of the processes of generating and storing the position data according to the modification of the first embodiment.

FIG. 27 is a diagram showing details of the process of determining the first to fourth areas and the movement path in the modification of the first embodiment.

FIG. 28 is a view schematically showing the configuration of the laser processing system according to a second embodiment.

FIG. 29 is a view showing the first position of the light shielding plate according to the second embodiment.

FIG. 30 is a view showing the second position of the light shielding plate according to the second embodiment.

FIG. 31 is a view showing the third position of the light shielding plate according to the second embodiment.

FIG. 32 is a view showing the fourth position of the light shielding plate according to the second embodiment.

FIG. 33 is a view schematically showing the configuration of the laser processing system according to a third embodiment.

FIG. 34 is a view showing a first position of the multi-point pattern.

FIG. 35 is a view showing a second position of the multi-point pattern.

FIG. 36 is a view showing a third position of the multi-point pattern.

FIG. 37 is a view showing a fourth position of the multi-point pattern.

FIG. 38 is a view schematically showing the configuration of an electronic device.

FIG. 39 is a diagram showing a manufacturing method of the electronic device.

### DESCRIPTION OF EMBODIMENTS

### Contents

1. Description of terms
   1.1 Diffractive optical element
2. Comparative example
   2.1 Configuration
   2.2 Operation
   2.3 Problem
3. First Embodiment
   3.1 Configuration
   3.2 Operation
   3.3 Effect
4. Modification of first embodiment
   4.1 Configuration
   4.2 Operation
   4.3 Effect
5. Second Embodiment
   5.1 Configuration
   5.2 Operation
   5.3 Effect
6. Third Embodiment
   6.1 Configuration
   6.2 Operation
   6.3 Effect
7. Electronic device manufacturing method
8. Configuration example of laser processing processor

Hereinafter, embodiments of the present disclosure will be described in detail with reference to the drawings. The embodiments described below shows some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

1.1 Diffractive Optical Element A diffractive optical element (DOE) is an optical element that utilizes diffractive phenomenon of light. For example, a DOE is manufactured by processing a microstructure designed by simulation onto a substrate using microfabrication technology. The DOE can convert laser light into various patterns. In the present disclosure, the laser light is converted into a multi-point pattern by the DOE.

### 2. Comparative Example

### 2.1 Configuration

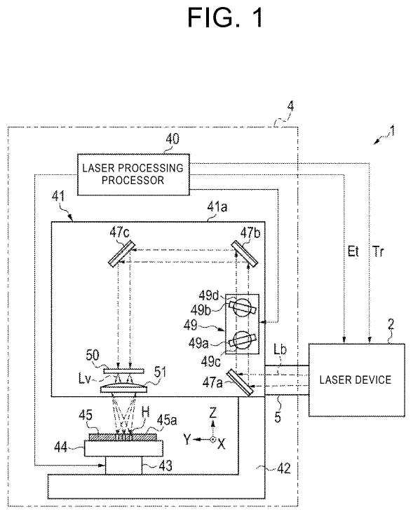

FIG. 1 schematically shows the configuration of a laser processing system 1 according to a comparative example. The comparative example is an example recognized by the applicant as known only by the applicant, and is not a publicly known example admitted by the applicant.

The laser processing system 1 includes a laser device 2 and a laser processing apparatus 4 as a main configuration. The laser processing system 1 is used for drilling by which a hole such as a via hole is formed in a glass substrate for an interposer.

The laser device 2 is a laser device that outputs ultraviolet pulse laser light. For example, the laser device 2 is a discharge-excitation-type laser device that outputs ultraviolet pulse laser light using F₂, ArF, KrF, XeCl, XeF, or the like as a laser medium. In the present embodiment, the laser device 2 is a KrF excimer laser device that outputs ultraviolet pulse laser light having a center wavelength of 248.4 nm. Hereinafter, the ultraviolet pulse laser light output from the laser device 2 is simply referred to as laser light Lb.

The laser device 2 and the laser processing apparatus 4 are connected by an optical path pipe 5. The optical path pipe 5 is arranged on the optical path of the laser light Lb between the emission port of the laser device 2 and the entrance port of the laser processing apparatus 4.

The laser processing apparatus 4 includes a laser processing processor 40, an optical device 41, a frame 42, an XYZ stage 43, and a table 44. The optical device 41 and the XYZ stage 43 are fixed to the frame 42.

The table 44 supports a workpiece 45. The workpiece 45 is a processing target on which drilling is performed. The workpiece 45 is a glass substrate for an interposer, and is, for example, an alkali-free glass substrate. Here, the workpiece 45 may be a substrate formed of quartz glass, an organic material, a silicon single crystal, ceramics, or the like. A plurality of holes H are formed in the workpiece 45 by so-called multi-point hole machining.

The XYZ stage 43 supports the table 44. The workpiece 45 is fixed on the table 44. The XYZ stage 43 can move the table 44 in an X direction, a Y direction, and a Z direction, and changes the position of the workpiece 45 by moving the table 44. The X direction, the Y direction, and the Z direction are orthogonal to one another. The X direction and the Y direction are parallel to a surface 45a of the workpiece 45. The Z direction is perpendicular to the surface 45a. Here, the XYZ stage 43 is an example of the “first actuator” according to the technology of the present disclosure.

The optical device 41 includes a housing 41a, high reflection mirrors 47a, 47b, 47c, an attenuator 49, a DOE 50, and a light concentrating optical system 51. Each configuration member in the optical device 41 is fixed to a holder (not shown), and is arranged at a predetermined position in the housing 41a.

The high reflection mirror 47a is arranged so as to reflect the laser light Lb that has passed through the optical path pipe 5, and to cause the reflected laser light Lb to pass through the attenuator 49 and be incident on the high reflection mirror 47b. The optical path pipe 5 and the housing 41a are purged with, for example, a purge gas. The purge gas is a nitrogen gas, an inert gas, or the like, and is a gas that hardly absorbs the laser light Lb.

The attenuator 49 is arranged on the optical path between the high reflection mirror 47a and the high reflection mirror 47b in the housing 41a. The attenuator 49 includes, for example, two partial reflection mirrors 49a, 49b and rotation stages 49c, 49d for the partial reflection mirrors 49a, 49b. The partial reflection mirrors 49a, 49b are optical elements whose transmittance varies depending on the incident angle of the laser light Lb. The incident angles of the laser light Lb on the partial reflection mirrors 49a, 49b are adjusted by the rotation stages 49c, 49d, respectively.

The high reflection mirrors 47b, 47c are arranged so as to reflect the laser light Lb that has passed through the attenuator 49, and to cause the reflected laser light Lb to be incident on the DOE 50.

The DOE 50 is arranged on the optical path of the laser light Lb reflected by the high reflection mirror 47c. The DOE 50 diffracts the laser light Lb incident from the high reflection mirror 47c, divides the laser light Lb into a plurality of beams of laser light Lv, and outputs the laser light Lv. The DOE 50 divides the laser light Lb in the X direction and the Y direction, thereby converting the laser light into a grid-like multi-point pattern. Here, the laser light Lb corresponds to the “first laser light” according to the technology of the present disclosure. The laser light Lv corresponds to the “second laser light” according to the technology of the present disclosure.

The light concentrating optical system 51 is arranged such that the plurality of beams of the laser light Lv output from the DOE 50 enters and the focal plane is located on the surface 45a of the workpiece 45. The light concentrating optical system 51 is, for example, an FO lens, concentrates the plurality of beams of the laser light Lv entering from the DOE 50, and generates a multi-point pattern in which a plurality of concentration spots are arranged in a grid-like manner.

The laser processing processor 40 transmits a target pulse energy Et and a light emission trigger Tr to the laser device 2. The target pulse energy Et is a target value of the pulse energy of the laser light Lb. The light emission trigger Tr is a trigger signal for causing the laser device 2 to output one pulse of the laser light Lb.

The laser processing processor 40 controls the laser device 2 and the XYZ stage 43 so that a multi-point pattern is radiated to respective step positions by a step-and-repeat method with respect to a processing area that requires drilling in the surface 45a of the workpiece 45.

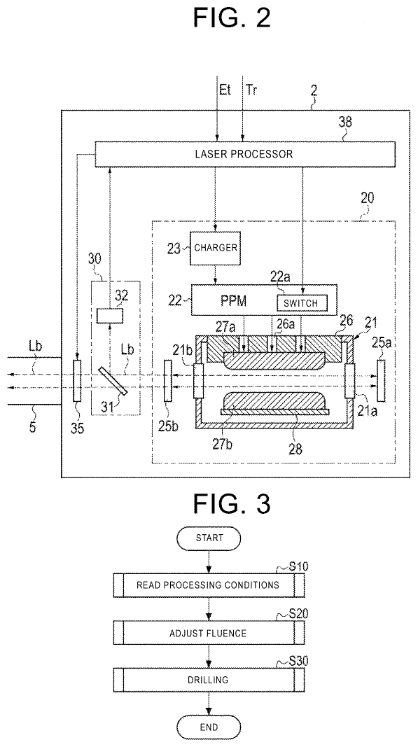

FIG. 2 schematically shows the configuration of the laser device 2. The laser device 2 includes an oscillator 20, a monitor module 30, a shutter 35, and a laser processor 38. The oscillator 20 includes a chamber 21, an optical resonator configured by a rear mirror 25a and an output coupling mirror (OC: Output Coupler) 25b, a charger 23, and a power supply unit (PPM: Pulsed Power Module) 22.

The chamber 21 is provided with windows 21a, 21b. A laser gas as a laser medium is enclosed in the chamber 21.

Further, an opening is formed in the chamber 21, and an electrically insulating plate 26 in which a plurality of feedthroughs 26a are embedded is provided so as to block the opening. The PPM 22 is arranged on the electrically insulating plate 26. A pair of discharge electrodes 27a, 27b as main electrodes and a ground plate 28 are arranged in the chamber 21. The shape of the discharge surface of the discharge electrodes 27a, 27b is rectangular.

The discharge electrodes 27a, 27b are arranged such that discharge surfaces of the both face each other to excite the laser medium by discharge. The discharge electrode 27a is supported by the electrically insulating plate 26 on a surface opposite to the discharge surface thereof. The discharge electrode 27a is connected to the feedthroughs 26a. The discharge electrode 27b is supported by the ground plate 28 on a surface opposite to the discharge surface thereof.

The PPM 22 includes a switch 22a, a charging capacitor (not shown), a pulse transformer (not shown), a magnetic compression circuit (not shown), and a peaking capacitor (not shown). The peaking capacitor is connected to the feedthroughs 26a via a connection portion (not shown). The charger 23 charges the charging capacitor based on control of the laser processor 38.

The switch 22a is controlled on/off by the laser processor 38. The laser processor 38 turns on the switch 22a in response to the light emission trigger Tr transmitted from the laser processing processor 40.

When the switch 22a is turned on, a current flows from the charging capacitor to the primary side of the pulse transformer, and a current in a reverse direction flows in the secondary side of the pulse transformer by electromagnetic induction. The magnetic compression circuit is connected to the secondary side of the pulse transformer and compresses the pulse width of current pulses. The peaking capacitor is charged by the current pulses. When the voltage of the peaking capacitor reaches a breakdown voltage of the laser gas, breakdown occurs at the laser gas between the discharge electrodes 27a, 27b to cause discharge. One pulse of the laser light Lb is generated by the discharge.

The rear mirror 25a is formed by coating a planar substrate with a high reflection film. The output coupling mirror 25b is formed by coating a planar substrate with a partial reflection film. The chamber 21 is arranged between the rear mirror 25a and the output coupling mirror 25b. The laser light Lb generated in the chamber 21 is amplified by the optical resonator and output from the output coupling mirror 25b.

The monitor module 30 includes a beam splitter 31 and an optical sensor 32. The beam splitter 31 is arranged on the optical path of the laser light Lb output from the output coupling mirror 25b, and reflects a part of the laser light Lb. The optical sensor 32 is arranged at a position where the laser light Lb reflected by the beam splitter 31 enters. The optical sensor 32 measures the pulse energy of the laser light Lb and transmits the measurement value to the laser processor 38.

The laser processor 38 changes the charge voltage of the charger 23 based on the measurement value of the pulse energy by the optical sensor 32 to control the pulse energy of the laser light Lb output from the laser device 2 to be the target pulse energy Et.

The shutter 35 is arranged on the optical path of the laser light Lb transmitted through the beam splitter 31. The shutter 35 is opened and closed in response to a command from the laser processor 38. The laser processor 38 controls the shutter 35 to control output of the laser light Lb from the laser device 2.

### 2.2 Operation

Next, operation of the laser processing system 1 according to the comparative example will be described. FIG. 3 schematically shows the flow of operation of the laser processing system 1 according to the comparative example. Prior to drilling, the workpiece 45 is set on the table 44 of the XYZ stage 43. First, the laser processing processor 40 reads processing conditions (step S10). Next, the laser processing processor 40 adjusts the fluence at the surface 45a of the workpiece 45 (step S20). Then, the laser processing processor 40 controls the laser device 2 and the XYZ stage 43 to perform drilling (step S30).

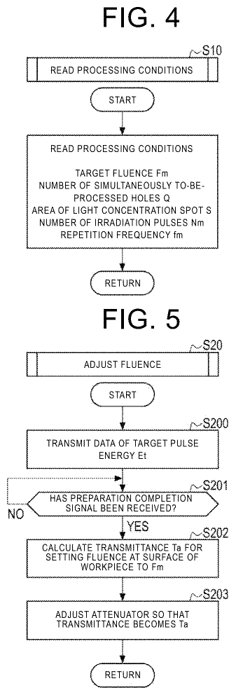

FIG. 4 shows details of a process of reading the processing conditions (step S10). The processing conditions read by the laser processing processor 40 in step S10 include, for example, a target fluence Fm, a number of simultaneously to-be-processed holes Q, an area of a light concentration spot S, a number of irradiation pulses Nm, and a repetition frequency fm. The processing conditions may be read from an external device (not shown), via a network, or from an input device operated by an operator.

The target fluence Fm is the pulse energy density per pulse of one light concentration spot on the surface 45a of the workpiece 45, and is a value greater than the a processing threshold of the workpiece 45. When the workpiece 45 is an alkali-free glass substrate, the target fluence Fm is several tens of J/cm².

The number of simultaneously to-be-processed holes Q is the number of holes H to be simultaneously processed, and corresponds to the number of the beams of the laser light Lv generated by the DOE 50, that is, the number of light concentration spots included in the multi-point pattern described above. The area of the light concentration spot S is calculated by, for example, a relational expression S=π(D/2)², where D is the diameter of the distribution of the light intensity that is 1/e² times or more of the peak intensity.

The number of irradiation pulses Nm is the number of pulses of the laser light Lb required to form a through hole that penetrates the workpiece 45 or a non-through hole having a target depth as the hole H. The repetition frequency fm is a repetition frequency of the laser light Lb output from the laser device 2, and is, for example, a rated value. The repetition frequency fm is, for example, 4 kHz.

FIG. 5 shows details of a fluence adjustment process (step S20). In step S20, first, the laser processing processor 40 transmits data of the target pulse energy Et required for drilling to the laser device 2 (step S200). After receiving the data, the laser device 2 controls the oscillator 20, and transmits a preparation completion signal to the laser processing processor 40 when becoming capable of outputting the laser light Lb having the target pulse energy Et.

Next, the laser processing processor 40 determines whether or not the preparation completion signal has been received from the laser device 2 (step S201). Upon determining that the preparation completion signal has been received (step S201.YES), the laser processing processor 40 calculates a transmittance Ta of the attenuator 49 for setting the fluence at the surface 45a of the workpiece 45 to the target fluence Fm (step S202). For example, the laser processing processor 40 calculates the transmittance Ta using the following expression (1). Here, T₀ is the transmittance of the optical device 41 when the transmittance of the attenuator 49 is 100%.

Ta=Fm×Q×S/(Et×T₀) (1)

Next, the laser processing processor 40 adjusts the attenuator 49 so that the transmittance becomes Ta (step S203). Specifically, the laser processing processor 40 controls the incident angles on the partial reflection mirrors 49a, 49b by controlling the rotation stages 49c, 49d, respectively, so that the transmittance of the attenuator 49 becomes Ta.

The laser processing processor 40 may adjust the target pulse energy Et in place of the transmittance of the attenuator 49 or in addition to the transmittance of the attenuator 49 so that the fluence at the surface 45a of the workpiece 45 becomes the target fluence Fm.

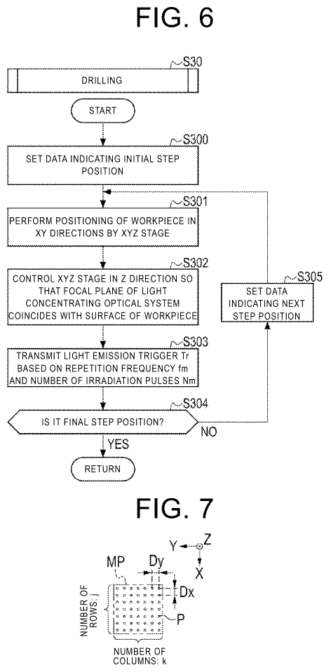

FIG. 6 shows details of a drilling process (step S30). In step S30, first, the laser processing processor 40 sets data indicating an initial step position on the surface 45a of the workpiece 45 (step S300). Next, the laser processing processor 40 controls the XYZ stage 43 based on the set data to perform positioning of the workpiece 45 in the XY directions (step S301). Further, the laser processing processor 40 controls the XYZ stage 43 in the Z direction so that the focal plane of the light concentrating optical system 51 coincides with the surface 45a of the workpiece 45 (step S302).

Next, the laser processing processor 40 transmits the light emission trigger Tr to the laser device 2 based on the repetition frequency fm and the number of irradiation pulses Nm (step S303). Consequently, the laser light Lb is output from the laser device 2 in synchronization with the light emission trigger Tr, and enters the laser processing apparatus 4 via the optical path pipe 5. The laser light Lb is reflected by the high reflection mirror 47a, attenuated by the attenuator 49, and then reflected by the high reflection mirrors 47b, 47c. The laser light Lb reflected by the high reflection mirror 47c is incident on the DOE 50. The DOE 50 divides the laser light Lb into a plurality of beams of the laser light Lv, and outputs the laser light Lv. The light concentrating optical system 51 concentrates the plurality of beams of the laser light Lv and forms a multi-point pattern on the surface 45a of the workpiece 45. Thus, a hole H is formed by laser ablation at a position corresponding to each light concentration spot included in the multi-point pattern.

Next, the laser processing processor 40 determines whether or not the current step position is the final step position (step S304). When it is determined not to be the final step position (step S304:NO), the laser processing processor 40 sets data indicating the next step position adjacent to the current step position (step S305), and returns processing to step S301.

The laser processing processor 40 repeatedly executes steps S301 to step S303 until the final step position is reached. When it is determined to be the final step position (step S304:YES), the laser processing processor 40 ends processing.

### 2.3 Problem

Next, a problem of the laser processing apparatus 4 according to the comparative example will be described with reference to FIGS. 7 to 10. In the present disclosure, an arrangement of points in the X direction is defined as a “column”, and an arrangement of points in the Y direction is defined as a “row”. The number of rows aligned in the X direction is referred to as “number of rows”, and the number of columns aligned in the Y direction is referred to as “number of columns”. Here, a point refers to the hole H or a light concentration spot P. In the following, the X direction may be referred to as a “column direction”, and the Y direction may be referred to as a “row direction”.

FIG. 7 shows an example of a multi-point pattern MP generated by the DOE 50 and the light concentrating optical system 51. The multi-point pattern MP is a pattern having a rectangular outer shape in which a plurality of light concentration spots P are arranged in a grid-like manner in the row direction and the column direction. Let j be the number of rows and k be the number of columns of the light concentration spots P included in the multi-point pattern MP. In the comparative example, j=7 and k=7. Here, an interval Dx of the multi-point pattern MP in the X direction and an interval Dy thereof in the Y direction may be the same or different.

FIG. 8 shows an example of a processing area 46 that requires drilling on the surface 45a of the workpiece 45. The processing area 46 is a rectangular area in which the holes H arranged in a grid-like manner are formed. Let r be the number of rows and s be the number of columns of holes H required to be formed in the processing area 46. In the comparative example, r=33 and s=40.

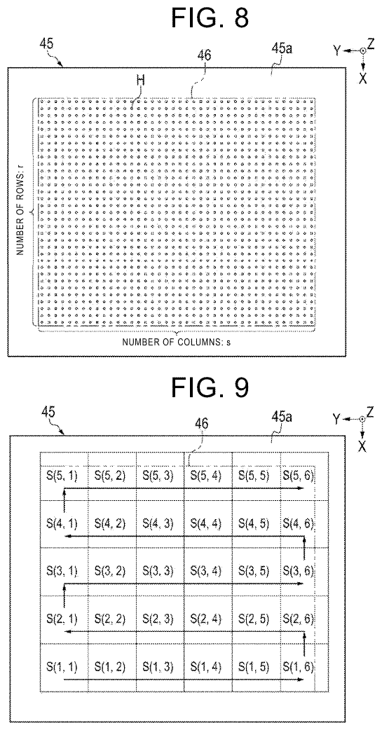

FIG. 9 shows an example of a plurality of step positions that the laser processing processor 40 sets on the surface 45a of the workpiece 45. S(m,n) represents the step position at which the multi-point pattern MP is radiated. Further, m represents the position in the X direction, and n represents the position in the Y direction. The laser processing processor 40 sets the number of step positions S(m,n) so that drilling is performed at the entire processing area 46. In the comparative example, 1≤m≤5, and 1≤n≤6.

At the time of drilling, the laser processing processor 40 controls the XYZ stage 43 to move the workpiece 45 so that the multi-point pattern MP is sequentially radiated at each step position S(m,n). Arrows shown in FIG. 9 indicate a movement path of the step positions S(m,n) at which the multi-point pattern MP is radiated. In the comparative example, S(1,1) is the initial step position, and S(5,6) is the final step position.

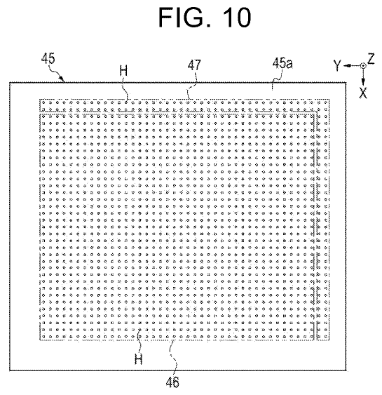

FIG. 10 shows an example of the surface 45a of the workpiece 45 after drilling. When the number of rows r and the number of columns s of the processing area 46 are not divisible by the number of rows j and the number of columns k of the multi-point pattern MP, respectively, unnecessary holes H are formed outside the processing area 46. Hereinafter, an area in which a plurality of unnecessary holes H are formed is referred to as a surplus area 47. When j=7, k=7, r=33, and s=40 as described above, the surplus area 47 having a number of surplus rows of two and a number of surplus columns of two occurs.

Since the number of divisions of the laser light Lb is determined for the DOE 50, it is conceivable to replace the DOE 50 with another DOE 50 in which the number of divisions is appropriate so that the surplus area 47 does not occur. However, when replacing the DOE 50, replacement and alignment of the DOE 50 are time consuming. Further, when the division count of the DOE 50 is changed, the fluence per light concentration spot is changed, and thus the fluence needs to be readjusted. As described above, when the DOE 50 is replaced, replacement, alignment, and readjustment of the fluence are each time consuming, and the throughput is lowered.

Therefore, the present disclosure provides a laser processing apparatus, a laser processing apparatus control method, and an electronic device manufacturing method that can maintain high throughput even when the number of rows r and the number of columns s of the processing area 46 are not divisible by the number of rows j and the number of columns k of the multi-point pattern MP, respectively.

### 3. First Embodiment

A laser processing system 1a according to a first embodiment of the present disclosure will be described. Any component same as that described above is denoted by an identical reference sign, and duplicate description thereof is omitted unless specific description is needed.

### 3.1 Configuration

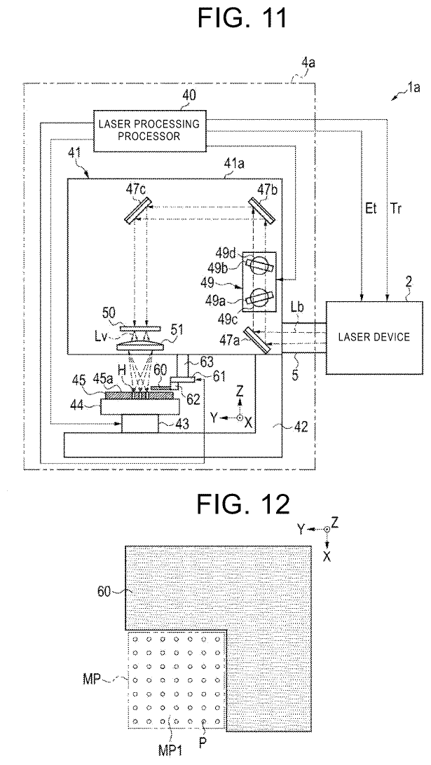

FIG. 11 schematically shows the configuration of the laser processing system 1a according to the first embodiment. The laser processing system 1a differs from the laser processing system 1 according to the comparative embodiment only in the configuration of a laser processing apparatus 4a. The laser processing apparatus 4a includes a light shielding plate 60 and an XY stage 61 in addition to the configuration of the laser processing apparatus 4 according to the comparative example.

The light shielding plate 60 is arranged in the vicinity of the surface 45a of the workpiece 45. The light shielding plate 60 is held by a holder 62 that is movable in the X direction and the Y direction on the XY stage 61. The XY stage 61 is fixed to the housing 41a via a bracket 63.

The XY stage 61 is a two-axis movement stage that moves the light shielding plate 60 in a direction perpendicular to the optical axis of the light concentrating optical system 51. Specifically, the XY stage 61 moves the light shielding plate 60 in the X direction and the Y direction via the holder 62. The XY stage 61 is controlled by the laser processing system 1a. The laser processing system 1a changes the relative position of the light shielding plate 60 with respect to the multi-point pattern MP by controlling the XY stage 61. The XY stage 61 is an example of the “second actuator” according to the technology of the present disclosure.

The light shielding plate 60 is formed of a material that is not easily drilled by the light concentration spot P so as to be able to shield a part of the multi-point pattern MP. The light shielding plate 60 is made of metal such as W, Ta, Mo, or the like having high melting point, or ceramics such as SiC, ZrO₂, BN or the like, silicon, diamond, or the like having a higher processing threshold than glass.

FIGS. 12 to 15 show the planar configuration of the light shielding plate 60. The light shielding plate 60 has, for example, an L-shape including a side parallel to the X direction and a side parallel to the Y direction, and is configured to be capable of shielding at least one row and at least one column of the light concentration spots P included in the multi-point pattern MP. In the present embodiment, the light shielding plate 60 is set to first to fourth positions by the laser processing processor 40.

FIG. 12 shows an example of the first position of the light shielding plate 60. When the light shielding plate 60 is set to the first position, the multi-point pattern MP passes through without being shielded by the light shielding plate 60. The multi-point pattern MP that has passed through without being shielded by the light shielding plate 60 as described above is referred to as a first multi-point pattern MP1.

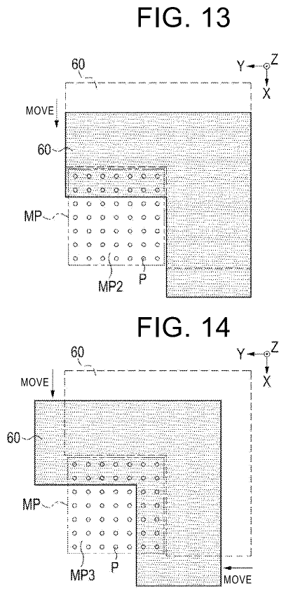

FIG. 13 shows an example of the second position of the light shielding plate 60. The second position is a position where the light shielding plate 60 is moved from the first position by a predetermined amount in the X direction. When the light shielding plate 60 is set to the second position, at least one row of the multi-point pattern MP is shielded by the light shielding plate 60. In the example shown in FIG. 13, two rows of the light concentration spots P from an end of the multi-point pattern MP are shielded. The multi-point pattern MP in which at least one row is shielded by the light shielding plate 60 as described above is referred to as a second multi-point pattern MP2.

FIG. 14 shows an example of the third position of the light shielding plate 60. The third position is a position where the light shielding plate 60 is moved from the first position by a predetermined amount in the X direction and in the Y direction. When the light shielding plate 60 is set to the third position, at least one row and at least one column of the multi-point pattern MP are shielded by the light shielding plate 60. In the example shown in FIG. 14, two rows and two columns of the light concentration spots P from ends of the multi-point pattern MP are shielded. The multi-point pattern MP in which at least one row and at least one column are shielded by the light shielding plate 60 as described above is referred to as a third multi-point pattern MP3.

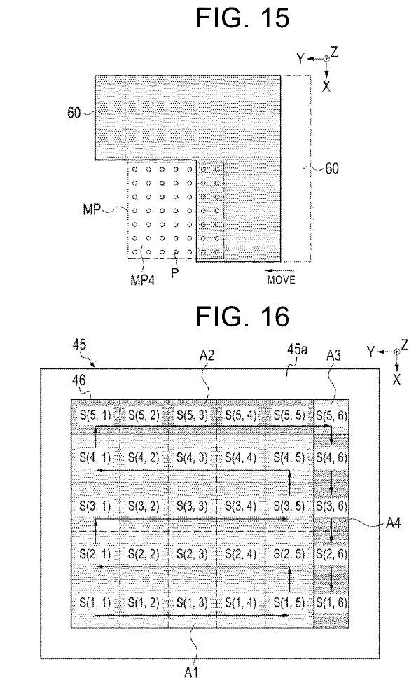

FIG. 15 shows an example of the fourth position of the light shielding plate 60. The fourth position is a position where the light shielding plate 60 is moved from the first position by a predetermined amount in the Y direction. When the light shielding plate 60 is set to the fourth position, at least one column of the multi-point pattern MP is shielded by the light shielding plate 60. In the example shown in FIG. 15, two columns of the light concentration spots P from an end of the multi-point pattern MP are shielded. The multi-point pattern MP in which at least one column is shielded by the light shielding plate 60 as described above is referred to as a fourth multi-point pattern MP4.

The XY stage 61 changes the relative position of the light shielding plate 60 with respect to the multi-point pattern MP in order to select one of the first to fourth multi-point patterns MP1 to MP4.

In the present embodiment, the laser processing processor 40 determines the number of rows and the number of columns that the light shielding plate 60 shields at each of the second to fourth positions based on the relationship between the number of rows r and the number of columns s of the processing area 46 and the number of rows j and the number of columns k of the multi-point pattern MP.

FIG. 16 shows an example of the plurality of step positions set by the laser processing processor 40. In the present embodiment, the laser processing processor 40 controls the XY stage 61 to select, from the first to fourth positions, a position at which the light shielding plate 60 is set for each step position S(m,n). That is, by controlling the XY stage 61, the laser processing processor 40 selects one of the first to fourth multi-point patterns MP1 to MP4 for each step position S(m,n).

The processing area 46 is divided into a first area A1, a second area A2, a third area A3, and a fourth area A4. In the present embodiment, the first area A1 includes the step positions S(m,n) of 1≤m≤4 and 1≤n≤5. The second area A2 includes the step positions S(m,n) of m=5 and 1≤n≤5. The third area A3 includes the step position S(m,n) of m=5 and n=6. The fourth area A4 includes the step positions S(m,n) of 1≤m≤4 and n=6. Each of the first to fourth areas A1 to A4 is a single block area that is not separated into plural areas.

In each step position S(m,n) in the first area A1, the first position is selected. In each step position S(m,n) in the second area A2, the second position is selected. In each step position S(m,n) in the third area A3, the third position is selected. In each step position S(m,n) in the fourth area A4, the fourth position is selected.

By controlling the XYZ stage 43, the laser processing processor 40 moves the workpiece 45 so that one of the first to fourth multi-point patterns MP1 to MP4 is radiated to each of the plurality of step positions S(m,n) set in the processing area 46. Further, the laser processing processor 40 determines the movement path of the workpiece 45 so that each step position S(m,n) of the first to fourth areas A1 to A4 sequentially becomes an irradiation target, and performs step-and-repeat control. The movement path is preferably a continuous path in which the step position of the irradiation target is changed to an adjacent step position.

### 3.2 Operation

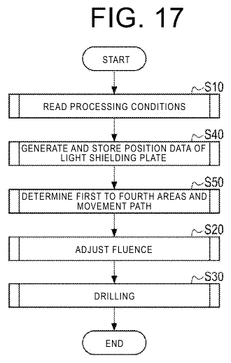

Next, operation of the laser processing system 1a according to the first embodiment will be described. FIG. 17 schematically shows the flow of operation of the laser processing system 1a according to the first embodiment. In the present embodiment, step S40 and step S50 are added between step S10 and step S20.

After reading the processing conditions in step S10, the laser processing processor 40 generates and stores the position data of the light shielding plate 60 (step S40). Next, the laser processing processor 40 determines the first to fourth areas A1 to A4 and the movement path (step S50). Then, the fluence is adjusted (step S20), and drilling is performed (step S30).

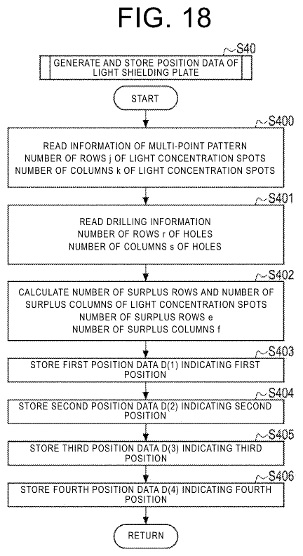

FIG. 18 shows details of processes of generating and storing the position data (step S40). In step S40, first, the laser processing processor 40 reads information of the multi-point pattern MP (step S400). Specifically, the laser processing processor 40 reads the number of rows j and the number of columns k of the light concentration spots P included in the multi-point pattern MP generated by the DOE 50 and the light concentrating optical system 51. The multi-point pattern MP may be read from an external device (not shown), via a network, or from an input device operated by an operator.

Further, the laser processing processor 40 reads drilling information that is information of the processing area 46 that requires drilling (step S401). Specifically, the laser processing processor 40 reads the number of rows r and the number of columns s of the holes H that need to be formed in the processing area 46. The drilling information may be read from an external device (not shown), via a network, or from an input device operated by an operator.

Next, the laser processing processor 40 calculates a number of surplus rows e and a number of surplus columns f of the light concentration spots P (step S402). Specifically, the laser processing processor 40 determines whether or not MOD(r,j)=0 using a function MOD(r,j). Here, the function MOD(r,j) outputs a remainder obtained by dividing the number of rows r by the number of rows j. When MOD(r,j)=0, e=0. When MOD(r,j)≠0, the number of surplus rows e is calculated by the following expression (2).

e=j−MOD(r,j) (2)

Further, the laser processing processor 40 determines whether or not MOD(s,k)=0 using a function MOD(s,k). Here, the function MOD(s,k) outputs a remainder obtained by dividing the number of columns s by the number of columns k. When MOD(s,k)=0, f=0. When MOD(s,k)≠0, the number of surplus columns f is calculated by the following expression (3).

f=k−MOD(s,k) (3)

As shown in the examples in FIGS. 7 and 8, when j=7, k=7, r=33, and s=40, then e=2 and f=2.

Next, the laser processing processor 40 stores first position data D(1) indicating the first position of the light shielding plate 60 in a memory (not shown) (step S403). As shown in FIG. 12, since the first position is a position independent of the number of surplus rows e and the number of surplus columns f, the first position data D(1) may be stored in the memory in advance.

Next, the laser processing processor 40 generates second position data D(2) indicating the second position of the light shielding plate 60 and stores the second position data D(2) in the memory (step S404). Specifically, as shown in FIG. 13, the laser processing processor 40 determines the second position of the light shielding plate 60 that shields rows of the multi-point pattern MP by the number of surplus rows e, and generates and stores the second position data D(2) indicating the second position. Here, when e=0, rows of the multi-point pattern MP do not need to be shielded, and thus generation and storing of the second position data D(2) are not necessary.

Next, the laser processing processor 40 generates third position data D(3) indicating the third position of the light shielding plate 60 and stores the third position data D(3) in the memory (step S405). Specifically, as shown in FIG. 14, the laser processing processor 40 determines the third position of the light shielding plate 60 that shields rows and columns of the multi-point pattern MP by the number of surplus rows e and the number of surplus columns f, and generates and stores the third position data D(3) indicating the third position. Here, when e=0 and f=0, rows and columns of the multi-point pattern MP do not need to be shielded, and thus generation and storing of the third position data D(3) are not necessary.

Next, the laser processing processor 40 generates fourth position data D(4) indicating the fourth position of the light shielding plate 60 and stores the fourth position data D(4) in the memory (step S406). Specifically, as shown in FIG. 15, the laser processing processor 40 determines the fourth position of the light shielding plate 60 that shields columns of the multi-point pattern MP by the number of surplus columns f, and generates and stores the fourth position data D(4) indicating the fourth position. Here, when f=0, columns of the multi-point pattern MP do not need to be shielded, and thus generation and storing of the fourth position data D(4) are not necessary.

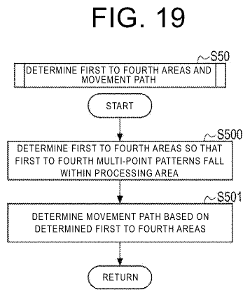

FIG. 19 shows details of a process of determining the first to fourth areas A1 to A4 and the movement path (step S50). In step S50, first, the laser processing processor 40 determines the first to fourth areas A1 to A4 so that the first to fourth multi-point patterns MP1 to MP4 fall within the processing area 46 as shown in FIG. 16 (step S500).

Next, the laser processing processor 40 determines the movement path of the workpiece 45 so that each step position of the first to fourth areas A1 to A4 sequentially becomes an irradiation target (step S501). For example, the laser processing processor 40 determines the movement path so that the step position of the irradiation position is changed in the order of the first area A1, the second area A2, the third area A3, and the fourth area A4.

Here, when e=0, only the first area A1 and the fourth area A4 are set, and when f=0, only the first area A1 and the second area A2 are set. Further, when e=0 and f=0, only the first area A1 is set.

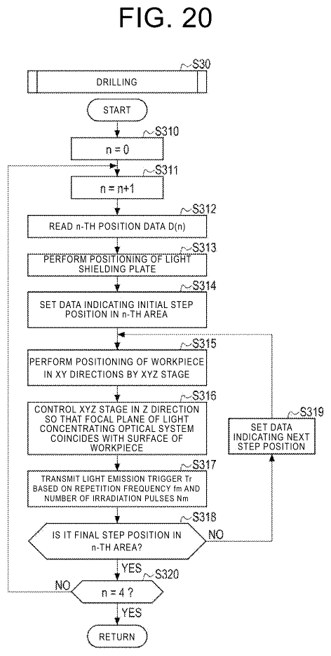

FIG. 20 shows details of the drilling process (step S30). Here, description will be provided on a case in which neither the number of surplus rows e nor the number of surplus columns f is 0. In step S30 of the present embodiment, first, the laser processing processor 40 sets a counter n to 0 (step S310). Next, the laser processing processor 40 adds 1 to the counter n (step S311), and reads n-th position data D(n) from the memory (step S312). The laser processing processor 40 performs positioning of the light shielding plate 60 at the n-th position based on the read n-th position data D(n) (step S313).

Next, the laser processing processor 40 sets data indicating an initial step position in an n-th area An (step S314). For example, the initial step position in the first area A1 is S(1,1). The initial step position in the second area A2 is S(5,1). The initial step position in the third area A3 is S(5,6). The initial step position in the fourth area A4 is S(4,6).

Next, the laser processing processor 40 executes steps S315, S316, S317. Since steps S315, S316, S317 are similar to steps S301, S302, S303 described in the comparative example, description thereof will be omitted.

After step S317, the laser processing processor 40 determines whether or not the current step position is the final step position in the n-th area An (step S318). For example, the final step position in the first area A1 is S(4,1). The final step position in the second area A2 is S(5,5). The final step position in the third area A3 is S(5,6). The final step position in the fourth area A4 is S(1,6).

When it is determined not to be the final step position (step S318:NO), the laser processing processor 40 sets data indicating the next step position on the movement path adjacent to the current step position (step S319), and returns processing to step S315.

The laser processing processor 40 repeatedly executes steps S315 to S317 until the final step position in the n-th area An is reached. When it is determined to be the final step position in the n-th area An (step S318:YES), the laser processing processor 40 determines whether or not the counter n is 4 (step S320).

When the counter n is not 4, the laser processing processor 40 returns processing to step S311. The laser processing processor 40 repeatedly executes steps S311 to S319 until the counter n becomes 4, and when it is determined that the counter n is 4 (step S320:YES), processing ends.

### 3.3 Effect

In the laser processing apparatus 4a according to the present embodiment, at the time of drilling, since the plurality of light concentration spots P corresponding to the surplus area 47 shown in FIG. 10 are shielded by the light shielding plate 60, drilling can be performed only in the processing area 46 without replacing the DOE 50. Therefore, even when the number of rows r and the number of columns s of the processing area 46 are not divisible by the number of rows j and the number of columns k of the multi-point pattern MP, respectively, high throughput can be maintained. Further, in the present embodiment, since the movement path is set so as to change the step position of the irradiation target to an adjacent step position, and the number of times of positioning the light shielding plate 60 is four at maximum, high throughput can be maintained.

Here, in the present embodiment, each of the first to fourth areas A1 to A4 is a single block area, but one or more areas of the first to fourth areas A1 to A4 may be divided not being a block area.

Further, although the light shielding plate 60 has an L-shape in the present embodiment, the light shielding plate 60 may be any shape capable of shielding a desired number of rows and a desired number of columns of the multi-point pattern MP in the X direction and the Y direction from ends. For example, the light shielding plate 60 may have a shape having a rectangular opening having a size that allows the entire multi-point pattern MP to pass therethrough.

### 4. Modification of First Embodiment

Next, a modification of the first embodiment will be described.

### 4.1 Configuration

The configuration of the laser processing system 1a according to the present modification is basically the same as that of the first embodiment. The present modification differs from the first embodiment in that the number of rows that the light shielding plate 60 shields in order to generate the second and third multi-point patterns MP2, MP3 is one, and the number of columns that the light shielding plate 60 shields in order to generate the third and fourth multi-point patterns MP3, MP4 is one.

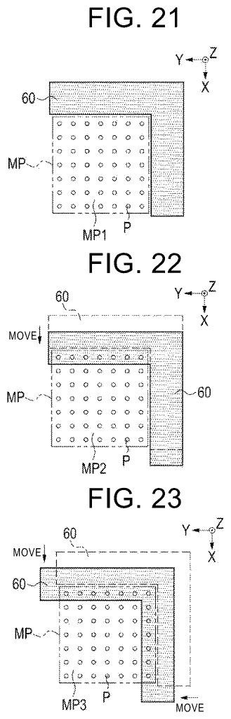

FIGS. 21 to 24 show the planar configuration of the light shielding plate 60 according to the modification of the first embodiment. The light shielding plate 60 has, for example, an L-shape including a side parallel to the X direction and a side parallel to the Y direction, and is configured to be capable of shielding one row and one column of the multi-point pattern MP. The light shielding plate 60 is set to first to fourth positions by the laser processing processor 40.

FIG. 21 shows the first position of the light shielding plate 60. When the light shielding plate 60 is set to the first position, the multi-point pattern MP passes through without being shielded by the light shielding plate 60, so that the first multi-point pattern MP1 is generated.

FIG. 22 shows the second position of the light shielding plate 60. When the light shielding plate 60 is set to the second position, only one row of the multi-point pattern MP is shielded by the light shielding plate 60, so that the second multi-point pattern MP2 is generated.

FIG. 23 shows the third position of the light shielding plate 60. When the light shielding plate 60 is set to the third position, only one row and one column of the multi-point pattern MP are shielded by the light shielding plate 60, so that the third multi-point pattern MP3 is generated.

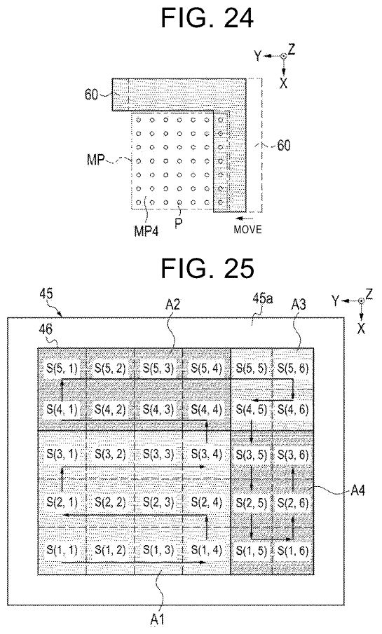

FIG. 24 shows the fourth position of the light shielding plate 60. When the light shielding plate 60 is set to the fourth position, only one column of the multi-point pattern MP is shielded by the light shielding plate 60, so that the fourth multi-point pattern MP4 is generated.

FIG. 25 shows an example of a plurality of step positions S(m,n) set by the laser processing processor 40 according to the modification of the first embodiment. In the present modification, the first area A1 includes the step positions S(m,n) of 1≤m≤3 and 1≤n≤4. The second area A2 includes the step positions S(m,n) of 4≤m≤5 and 1≤n≤4. The third area A3 includes the step positions S(m,n) of 4≤m≤5 and 5≤n≤6. The fourth area A4 includes the step positions S(m,n) of 1≤m≤3 and 5≤n≤6.

The laser processing processor 40 determines the movement path of the workpiece 45 so that each step position S(m,n) of the first to fourth areas A1 to A4 sequentially becomes the irradiation target. In the present modification, S(3,6) is the final step position of the movement path in the processing area 46.

### 4.2 Operation

Next, operation of the laser processing system 1a according to the modification of the first embodiment will be described. The flow of operation of the laser processing system 1a according to the present modification is basically the same as the that of the laser processing system 1a according to the first embodiment shown in FIG. 17, but processes of step S40 and step S50 differ.

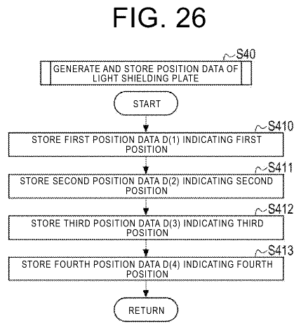

FIG. 26 shows details of the processes of generating and storing position data (step S40) according to the modification of the first embodiment. In the present modification, since the number of rows and the number of columns of the light concentration spots P shielded by the light shielding plate 60 are each a fixed value being one, steps S400 to S402 for calculating the number of surplus rows e and the number of surplus columns f shown in FIG. 18 are not executed in step S40.

In the present modification, in step S40, first, the laser processing processor 40 stores the first position data D(1) indicating the first position of the light shielding plate 60 shown in FIG. 21 in the memory (step S410). Further, the laser processing processor 40 stores the second position data D(2) indicating the second position of the light shielding plate 60 shown in FIG. 22 in the memory (step S411). Further, the laser processing processor 40 stores the third position data D(3) indicating the third position of the light shielding plate 60 shown in FIG. 23 in the memory (step S412). Further, the laser processing processor 40 stores the fourth position data D(4) indicating the fourth position of the light shielding plate 60 shown in FIG. 24 in the memory (step S413).

In the present modification, since the first to fourth positions are positions independent of the number of surplus rows e and the number of surplus columns f, the first to fourth position data D(1) to D(4) may be stored in the memory in advance.

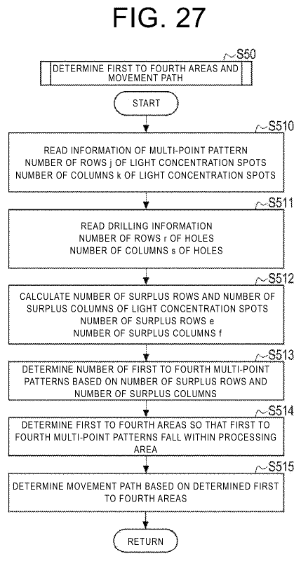

FIG. 27 shows details of the process of determining the first to fourth areas A1 to A4 and the movement path (step S50) in the modification of the first embodiment. In the present modification, first, the laser processing processor 40 executes steps S510 to S512 to calculate the number of surplus rows e and the number of surplus columns f Steps S510 to S512 are processes similar to steps S400 to S402 shown in FIG. 18.

The laser processing processor 40 determines the number of the first to fourth multi-point patterns MP1 to MP4 based on the calculated number of surplus rows e and the calculated number of surplus columns f (step S513). In order to shield columns of the light concentration spots P corresponding to the number of the surplus columns e, e pieces of the second multi-point pattern MP2 are required in the X direction. Further, in order to shield columns of the light concentration spots P corresponding to the number of the surplus columns f, f pieces of the fourth multi-point pattern MP4 are required in the Y direction.

Next, the laser processing processor 40 determines the first to fourth areas A1 to A4 so that the first to fourth multi-point patterns MP1 to MP4 fall within the processing area 46 as shown in FIG. 25 (step S514). Then, the laser processing processor 40 determines the movement path of the workpiece 45 so that each step position of the first to fourth areas A1 to A4 sequentially becomes the irradiation target (step S515). Steps S514, S515 are processes similar to steps S500, S501 shown in FIG. 19.

The drilling process according to the present modification is similar to the drilling process shown in FIG. 20. Here, the initial step position and the final step position in the n-th area An differ depending on the first to fourth areas A1 to A4 determined in step S50.

In the example shown in FIG. 25, the initial step position in the first area A1 is S(1,1). The initial step position in the second area A2 is S(4,4). The initial step position in the third area A3 is S(5,5). The initial step position in the fourth area A4 is S(3,5).

Further, the final step position in the first area A1 is S(3,4). The final step position in the second area A2 is S(5,4). The final step position in the third area A3 is S(4,5). The final step position in the fourth area A4 is S(3,6).

### 4.3 Effect

Also in the present modification, since the light shielding plate 60 shields the rows of the light concentration spot P corresponding to the number of surplus rows e and the columns of the light concentration spot P corresponding to the number of surplus columns f at the time of drilling, high throughput can be maintained as in the first embodiment. Further, in the present modification, since the movement distance of the light shielding plate 60 is only one row or one column, the movement time of the light shielding plate 60 is shortened and the positioning accuracy is improved. As a result, the throughput is further improved.

Here, in the present modification as well, each of the first to fourth areas A1 to A4 is a single block area, but one or more areas of the first to fourth areas A1 to A4 may be divided not being a block area.

### 5. Second Embodiment

A laser processing system 1b according to a second embodiment of the present disclosure will be described. Any component same as that described above is denoted by an identical reference sign, and duplicate description thereof is omitted unless specific description is needed.

### 5.1 Configuration

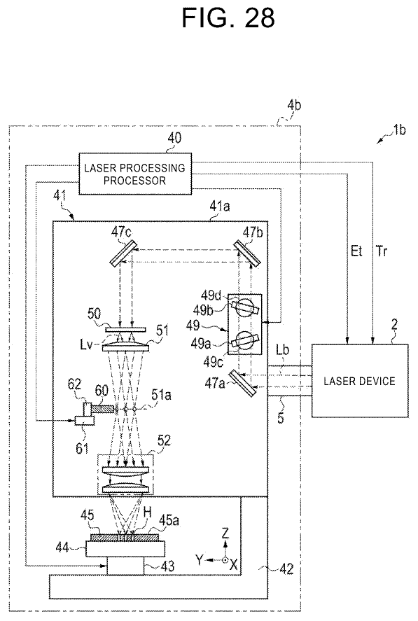

FIG. 28 schematically shows the configuration of the laser processing system 1b according to the second embodiment. The laser processing system 1b differs from the laser processing system 1a according to the first embodiment only in the configuration of a laser processing apparatus 4b. The laser processing apparatus 4b includes a reduced transfer imaging optical system 52 in addition to the configuration of the laser processing apparatus 4a according to the first embodiment.

The reduced transfer imaging optical system 52 is arranged on the optical path of the plurality of beams of the laser light Lv output from the light concentrating optical system 51. The reduced transfer imaging optical system 52 reduces the multi-point pattern MP formed on a focal plane 51a of the light concentrating optical system 51 and forms a transfer image thereof on the surface 45a of the workpiece 45.

In the present embodiment, the light shielding plate 60 is arranged on the focal plane 51a of the light concentrating optical system 51. The light shielding plate 60 is held by the holder 62 that is movable in the X direction and the Y direction on the XY stage 61. The XY stage 61 is fixed to the housing 41a and controlled by the laser processing processor 40.

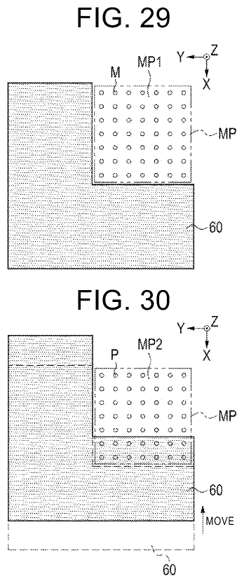

FIGS. 29 to 32 show the planar configuration of the light shielding plate 60 according to the second embodiment. Since the reduced transfer imaging optical system 52 transfers and images an inverted image of the multi-point pattern MP on the surface 45a of the workpiece 45, the planar shape of the light shielding plate 60 according to the present embodiment is a shape obtained by reversing the planar shape of the light shielding plate 60 according to the first embodiment in the X direction and in the Y direction.

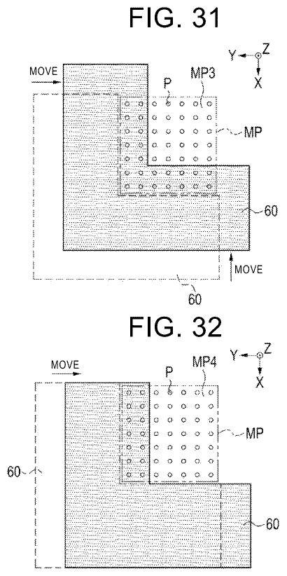

FIG. 29 shows a first position of the light shielding plate 60. FIG. 30 shows a second position of the light shielding plate 60. FIG. 31 shows a third position of the light shielding plate 60. FIG. 32 shows a fourth position of the light shielding plate 60. The first to fourth positions according to the present embodiment are similar to the first to fourth positions according to the first embodiment except that they are inverted in the X direction and in the Y direction.

### 5.2 Operation

Operation of the laser processing system 1b according to the second embodiment is similar to the operation of the laser processing system 1a according to the first embodiment except that the movement direction for moving the light shielding plate 60 is opposite to that of the first embodiment.

### 5.3 Effect

For example, when the workpiece 45 is an alkali-free glass substrate, the target fluence Fm at the surface 45a of the workpiece 45 is required to be as high as several tens of J/cm². Therefore, when the light shielding plate 60 is arranged in the vicinity of the surface 45a of the workpiece 45 as in the first embodiment, the light shielding plate 60 may be damaged. On the other hand, in the present embodiment, since the light shielding plate 60 is arranged on the focal plane 51a of the light concentrating optical system 51, the fluence of the light shielding plate 60 is lowered, and damage on the light shielding plate 60 is suppressed. Specifically, when the magnification of the reduced transfer imaging optical system 52 is defined as 1/M, the fluence at the focal plane 51a is 1/M² times of the target fluence Fm at the surface 45a of the workpiece 45. Here, M>1 is satisfied.

Further, to suppress damage on the light shielding plate 60, it is preferable to use the light shielding plate 60 having a large thickness. However, when the pitch of the holes H to be formed in the workpiece 45 is small or the numerical aperture NA is large, it is difficult to arrange the light shielding plate 60 having a large thickness on the surface 45a of the workpiece 45. On the other hand, in the present embodiment, since the light shielding plate 60 is arranged on the focal plane 51a where the light concentration spots P are arranged at a pitch larger than the pitch of the holes H, the light shielding plate 60 having a larger thickness than that of the first embodiment can be used.

Here, the present embodiment can also be modified in a similar manner as the first embodiment.

### 6. Third Embodiment

A laser processing system 1c according to a third embodiment of the present disclosure will be described. Any component same as that described above is denoted by an identical reference sign, and duplicate description thereof is omitted unless specific description is needed.

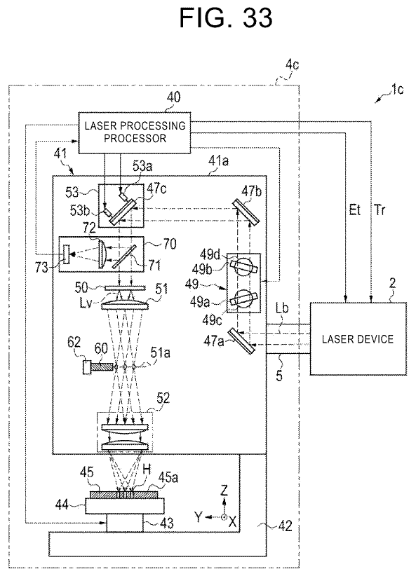

6.1 Configuration FIG. 33 schematically shows the configuration of the laser processing system 1c according to the third embodiment. The laser processing system 1c differs from the laser processing system 1b according to the second embodiment only in the configuration of a laser processing apparatus 4c. The laser processing apparatus 4c includes a beam steering device 53 and a pointing measurement device 70 in addition to the configuration of the laser processing apparatus 4b according to the second embodiment.

In the present embodiment, the XY stage 61 is not provided, and the light shielding plate 60 is fixed to the housing 41a via the holder 62. That is, in the present embodiment, the light shielding plate 60 does not move.

The beam steering device 53 includes two actuators 53a, 53b for changing the angle of the high reflection mirror 47c. The actuators 53a, 53b are controlled by the laser processing processor 40 to change the angle of the high reflection mirror 47c about two perpendicular axes.

The pointing measurement device 70 includes a beam splitter 71, a light concentrating lens 72, and a two-dimensional optical sensor 73. The beam splitter 71 is arranged on the optical path of the laser light Lb between the beam steering device 53 and the DOE 50. The beam splitter 71 reflects a part of the laser light Lb reflected by the high reflection mirror 47c and transmits the other part of the laser light Lb. The laser light Lb transmitted through the beam splitter 71 enters the DOE 50.

The light concentrating lens 72 is arranged on the optical path of the laser light Lb reflected by the beam splitter 71, and concentrates the laser light Lb. The two-dimensional optical sensor 73 is arranged at a position where the light concentrating lens 72 can detect the concentrated image generated on the focal plane. The two-dimensional optical sensor 73 may be a two-dimensional position sensitive detector (PSD) or a two-dimensional photodiode array. The two-dimensional optical sensor 73 measures the position of the concentrated image, that is, the pointing of the laser light Lb, and transmits the measurement value to the laser processing processor 40.

In the present embodiment, the laser processing processor 40 changes the incident angle of the laser light Lb incident on the DOE 50 by controlling the angle of the high reflection mirror 47c via the beam steering device 53. In response to the change of the incident angle of the laser light Lb incident on the DOE 50, the multi-point pattern MP moves within the focal plane 51a. That is, the beam steering device 53 is an example of the “second actuator” according to the technology of the present disclosure.

In the present embodiment, the laser processing processor 40 performs feedback control so that the relative position of the light shielding plate 60 with respect to the multi-point pattern MP becomes a target position based on the measurement value of the pointing transmitted from the pointing measurement device 70.

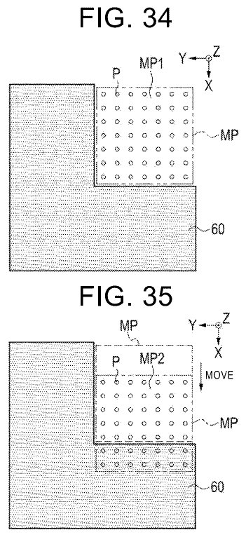

FIGS. 34 to 37 show the planar configuration of the light shielding plate 60 according to the third embodiment. The planar shape of the light shielding plate 60 according to the present embodiment is similar to the planar shape of the light shielding plate 60 according to the second embodiment. In the present embodiment, the relative position of the light shielding plate 60 with respect to the multi-point pattern MP is changed by moving the multi-point pattern MP with the light shielding plate 60 fixed.

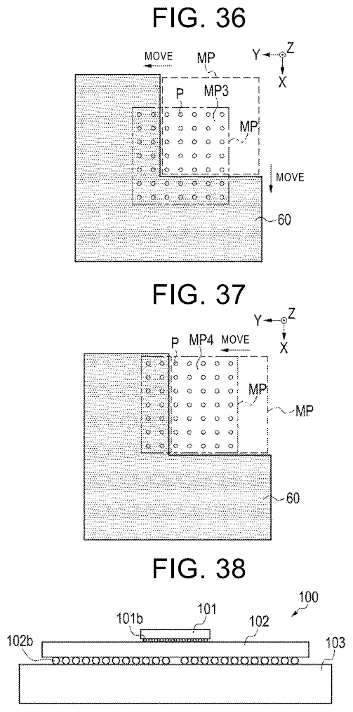

FIG. 34 shows a first position of the multi-point pattern MP. FIG. 35 shows a second position of the multi-point pattern MP. FIG. 36 shows a third position of the multi-point pattern MP. FIG. 37 shows a fourth position of the multi-point pattern MP. In the present embodiment, similarly to the second embodiment, the first to fourth multi-point patterns MP1 to MP4 are generated at the first to fourth positions, respectively.

### 6.2 Operation

In the operation of the laser processing system 1c according to the third embodiment, the laser processing processor 40 selects one of the first to fourth positions by controlling the beam steering device 53 instead of the XY stage 61. Other operation is similar to that of the laser processing system 1b according to the second embodiment.

### 6.3 Effect

In the present embodiment, since the multi-point pattern MP is moved by the beam steering device 53, movement and positioning of the relative position of the light shielding plate 60 with respect to the multi-point pattern MP can be performed at a higher speed than when the light shielding plate 60 is moved. Accordingly, the throughput is improved.

Although the pointing measurement device 70 is not an essential component, movement and positioning of the relative position of the light shielding plate 60 with respect to the multi-point pattern MP can be performed with high accuracy by performing feedback control using the pointing measurement device 70.

In the embodiments described above, the incident angle of the laser light Lb incident on the DOE 50 is changed by the beam steering device 53, but the incident angle of the laser light Lb may be changed by using an acoustic optical element. As the acoustic optical element, it is preferable to use an acoustic optical element of quartz that can also be used for ultraviolet rays, and to control the incident angle of the laser light Lb in the two axis directions. The acoustic optical element is an example of the “second actuator” according to the technology of the present disclosure.

Here, the present embodiment can also be modified in a similar manner as the first embodiment.

### 7. Electronic Device Manufacturing Method

The laser processing method according to each of the embodiments and the modifications described above can be applied to forming a through hole in a glass substrate included in an interposer 102 in manufacturing an electronic device 100 described below.

FIG. 38 schematically shows the configuration of the electronic device 100. The electronic device 100 shown in FIG. 38 includes an integrated circuit chip 101, the interposer 102, and a circuit substrate 103. The integrated circuit chip 101 is a chip-shaped integrated circuit substrate in which an integrated circuit is formed on, for example, a silicon substrate. The integrated circuit chip 101 is provided with a plurality of bumps 101b electrically connected to the integrated circuit.

The interposer 102 includes an insulating glass substrate in which a plurality of through holes are formed, and a conductor that electrically connects the front and back of the glass substrate is provided in each through hole. A plurality of lands connected to the bumps 101b provided on the integrated circuit chip 101 are formed on one surface of the interposer 102, and each land is electrically connected to one of the conductors in the through holes. A plurality of bumps 102b are provided on the other surface of the interposer 102, and each bump 102b is electrically connected to one of the conductors in the through holes.

A plurality of lands connected to the respective bumps 102b are formed on one surface of the circuit substrate 103. The circuit substrate 103 includes a plurality of terminals electrically connected to the lands.

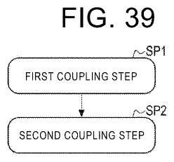

FIG. 39 shows a manufacturing method of the electronic device 100. As shown in FIG. 39, the manufacturing method of the electronic device 100 in the present description includes a first coupling step SP1 and a second coupling step SP2. In the first coupling step SP1, the integrated circuit chip 101 and the interposer 102 are coupled. Specifically, each bump 101b of the integrated circuit chip 101 is arranged on a corresponding land of the interposer 102 to electrically connect the bumps 101b and the lands. Thus, the integrated circuit chip 101 and the interposer 102 are electrically connected to each other.

In the second coupling step SP2, the interposer 102 and the circuit substrate 103 are coupled. Specifically, each bump 102b of the interposer 102 is arranged on a corresponding land of the circuit substrate 103 to electrically connect the bumps 102b and the lands. Thus, the integrated circuit chip 101 is electrically connected to the circuit substrate 103 via the interposer 102. Through the above steps, the electronic device 100 is manufactured.

### 8. Configuration Example of Laser Processing Processor

In the present disclosure, the laser processing processor 40 is configured by, for example, a central processing unit (CPU). The laser processing processor 40 executes various types of processing described above based on a program stored in the memory. Some or all of the functions of the laser processing processor 40 may be realized by using an integrated circuit such as a field programmable gate array (FPGA) or an application specific integrated circuit (ASIC).

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A laser processing apparatus comprising:
a diffractive optical element configured to divide first laser light into a plurality of beams of second laser light and output the plurality of beams of second laser light;
a light concentrating optical system configured to generate a multi-point pattern in which a plurality of concentration spots are arranged in a grid-like manner in a row direction and a column direction by concentrating the plurality of beams of second laser light;
a first actuator configured to move a workpiece;
a light shielding plate capable of shielding at least one row and at least one column of the multi-point pattern;
a second actuator configured to change a relative position of the light shielding plate with respect to the multi-point pattern so as to select one of a first multi-point pattern generated by the multi-point pattern passing through without being shielded by the light shielding plate, a second multi-point pattern generated by at least one row of the multi-point pattern being shielded by the light shielding plate, a third multi-point pattern generated by at least one row and at least one column of the multi-point pattern being shielded by the light shielding plate, and a fourth multi-point pattern generated by at least one column of the multi-point pattern being shielded by the light shielding plate; and
a laser processing processor configured to control the first actuator to move the workpiece such that any one of the first to fourth multi-point patterns is radiated to each of a plurality of step positions set in a processing area that requires drilling on a surface of the workpiece, and control the second actuator to select one of the first to fourth multi-point patterns for each of the step positions.

2. The laser processing apparatus according to claim 1,
wherein a relationship of e=j-MOD(r,j) is satisfied, where j is a number of rows of the multi-point pattern, r is a number of rows of holes to be formed in the processing area, and e is a number of rows that the light shielding plate shields for generating each of the second multi-point pattern and the third multi-point pattern, and
a relationship of f=k-MOD(s,k) is satisfied, where k is a number of columns of the multi-point pattern, s is a number of columns of the holes to be formed in the processing area, and f is a number of columns that the light shielding plate shields for generating each of the third multi-point pattern and the fourth multi-point pattern.

3. The laser processing apparatus according to claim 1,
wherein a number of rows that the light shielding plate shields for generating each of the second multi-point pattern and the third multi-point pattern is one, and
a number of columns that the light shielding plate shields for generating each of the third multi-point pattern and the fourth multi-point pattern is one.

4. The laser processing apparatus according to claim 1,
wherein the laser processing processor determines first to fourth areas where the first to fourth multi-point patterns are radiated respectively so that drilling is performed only in the processing area.

5. The laser processing apparatus according to claim 4,
wherein each of the first to fourth areas in the processing area is a single block area.

6. The laser processing apparatus according to claim 4,
wherein the laser processing processor controls the first actuator to change the step position of an irradiation target to the step position adjacent thereto.

7. The laser processing apparatus according to claim 1,
wherein the second actuator is a two-axis movement stage that moves the light shielding plate in a direction perpendicular to an optical axis of the light concentrating optical system.

8. The laser processing apparatus according to claim 1,
wherein the second actuator is a beam steering device that changes the relative position of the light shielding plate with respect to the multi-point pattern by changing an incident angle of the first laser light incident on the diffractive optical element.

9. The laser processing apparatus according to claim 8,
further comprising a pointing measurement device arranged on an optical path of the first laser light between the beam steering device and the diffractive optical element, and configured to measure a pointing of the first laser light.

10. The laser processing apparatus according to claim 9,
wherein the laser processing processor performs feedback control on the relative position of the light shielding plate with respect to the multi-point pattern based on a measurement value of the pointing by the pointing measurement device.

11. The laser processing apparatus according to claim 1,
wherein the workpiece is arranged such that the surface thereof coincides with a focal plane of the light concentrating optical system.

12. The laser processing apparatus according to claim 1,
further comprising a reduced transfer imaging optical system that reduces the multi-point pattern generated by the light concentrating optical system and forms a transfer image on the surface of the workpiece.

13. The laser processing apparatus according to claim 12,
wherein the light shielding plate is arranged on a focal plane of the light concentrating optical system.

14. A laser processing apparatus control method, comprising:
controlling a first actuator to move a workpiece such that any one of first to fourth multi-point patterns is radiated to each of a plurality of step positions set in a processing area that requires drilling on a surface of the workpiece; and
controlling a second actuator to select one of the first to fourth multi-point patterns for each of the step positions,
the laser processing apparatus including:
a diffractive optical element configured to divide first laser light into a plurality of beams of second laser light and output the plurality of beams of second laser light;
a light concentrating optical system configured to generate a multi-point pattern in which a plurality of concentration spots are arranged in a grid-like manner in a row direction and a column direction by concentrating the plurality of beams of second laser light;
the first actuator configured to move the workpiece;
a light shielding plate capable of shielding at least one row and at least one column of the multi-point pattern; and
the second actuator configured to change a relative position of the light shielding plate with respect to the multi-point pattern so as to select one of the first multi-point pattern generated by the multi-point pattern passing through without being shielded by the light shielding plate, the second multi-point pattern generated by at least one row of the multi-point pattern being shielded by the light shielding plate, the third multi-point pattern generated by at least one row and at least one column of the multi-point pattern being shielded by the light shielding plate, and the fourth multi-point pattern generated by at least one column of the multi-point pattern being shielded by the light shielding plate.

15. An electronic device manufacturing method, comprising:
forming a plurality of through holes in a glass substrate as a workpiece with a laser processing apparatus;
coupling and electrically connecting an interposer and an integrated circuit chip to each other, the interposer including the glass substrate and a conductor arranged in each of the plurality of through holes; and
coupling and electrically connecting the interposer and a circuit substrate to each other, the laser processing apparatus including:
a diffractive optical element configured to divide first laser light into a plurality of beams of second laser light and output the plurality of beams of second laser light;
a light concentrating optical system configured to generate a multi-point pattern in which a plurality of concentration spots are arranged in a grid-like manner in a row direction and a column direction by concentrating the plurality of beams of second laser light;
a first actuator configured to move the workpiece;
a light shielding plate capable of shielding at least one row and at least one column of the multi-point pattern;
a second actuator configured to change a relative position of the light shielding plate with respect to the multi-point pattern so as to select one of a first multi-point pattern generated by the multi-point pattern passing through without being shielded by the light shielding plate, a second multi-point pattern generated by at least one row of the multi-point pattern being shielded by the light shielding plate, a third multi-point pattern generated by at least one row and at least one column of the multi-point pattern being shielded by the light shielding plate, and a fourth multi-point pattern generated by at least one column of the multi-point pattern being shielded by the light shielding plate; and
a laser processing processor configured to control the first actuator to move the workpiece such that any one of the first to fourth multi-point patterns is radiated to each of a plurality of step positions set in a processing area that requires drilling on a surface of the workpiece, and control the second actuator to select one of the first to fourth multi-point patterns for each of the step positions.
